(19) United States
(12) Patent Application Publication
(10) Pub. No.: US 2025/0387855 A1
(43) Pub. Date: Dec. 25, 2025

(54) LASER OPTIC SYSTEM AND LASER CRYSTALLIZATION APPARATUS INCLUDING THE SAME

(71) Applicant: Samsung Display Co., Ltd., Yongin-Si (KR)

(72) Inventors: Dong-Min LEE, Yongin-si (KR); DONGGYU JIN, Yongin-si (KR); Jong Oh SEO, Yongin-si (KR)

(21) Appl. No.: 18/982,819

(22) Filed: Dec. 16, 2024

(30) Foreign Application Priority Data
Jun. 25, 2024 (KR) 10-2024-0083068

(51) Int. Cl. B23K 26/067; B23K 26/06

(52) U.S. Cl. CPC B23K 26/0676; B23K 26/0648

(57) ABSTRACT

A laser optic system includes a beam division unit configured to divide a laser beam into a first sub-beam and a second sub-beam, an inverting optic system configured to generate a first deformed beam by inverting a cross-sectional shape of the first sub-beam and reducing a diameter of the cross-sectional shape of the first sub-beam, a non-inverting optic system configured to generate a second deformed beam by reducing a diameter of a cross-sectional shape of the second sub-beam, and an integrated optic system configured to generate a line beam by integrating the first deformed beam and the second deformed beam.

### CROSS-REFERENCE TO RELATED APPLICATION

This application claims priority to and the benefit of Korean Patent Application No. 10-2024-0083068 filed on Jun. 25, 2024, in the Korean Intellectual Property Office under 35 U.S.C. § 119, the entire contents of which are incorporated herein by reference.

### BACKGROUND

### 1. Field

The present disclosure relates to a laser optic system and a laser crystallization apparatus including the same.

### 2. Description of the Related Art

In the manufacturing process of organic light emitting diode (OLED) displays, a laser crystallization apparatus for excimer laser annealing (ELA) is used to crystallize amorphous silicon into polycrystalline silicon. Excimer laser annealing is a process where high laser energy, generated by applying a high-voltage discharge to a gas laser source, is used for heat treatment. However, excimer laser annealing may have a longer processing time because of its low oscillation frequency. Therefore, in order to prevent this, a laser crystallization apparatus for solid laser annealing (SLA) is being introduced. Solid laser annealing uses a solid-state laser source in the ultraviolet wavelength range, which not only reduces maintenance costs compared to excimer laser annealing but also shortens processing time due to its higher oscillation frequency.

However, solid-state laser annealing is a high-frequency process that may cause a thermal lensing effect, where the lens heats up due to its thermal energy. In this case, the focal length of the optic system, etc. may change, causing the profile of the laser beam to become asymmetrical, which may reduce the uniformity of the beam.

### SUMMARY

The present disclosure provides a laser optic system and a laser crystallization apparatus including the same that may minimize decrease of energy, improve beam uniformity, and enhance the crystallization margin.

According to an embodiment, a laser optic system includes a beam division unit configured to divide a laser beam into a first sub-beam and a second sub-beam, an inverting optic system configured to generate a first deformed beam by inverting a cross-sectional shape of the first sub-beam and reducing a diameter of the cross-sectional shape of the first sub-beam, a non-inverting optic system configured to generate a second deformed beam by reducing a diameter of a cross-sectional shape of the second sub-beam, and an integrated optic system configured to generate a line beam by integrating the first deformed beam and the second deformed beam.

The inverting optic system may include a first inverting convex lens positioned on a propagation path of the first sub-beam, and a second inverting convex lens positioned to be spaced apart from the first inverting convex lens and having a second curvature that is greater than a first curvature that is a curvature of the first inverting convex lens, where the cross-sectional shape of the first sub-beam is inverted when the first sub-beam sequentially passes through the first inverting convex lens and the second inverting convex lens.

The first sub-beam may form the first deformed beam by a long axis inversion that is an inversion along a long axis of the cross-sectional shape of the first sub-beam or a short axis inversion that is an inversion along a short axis of the cross-sectional shape of the first sub-beam, when the first sub-beam sequentially passes through the first inverting convex lens and the second inverting convex lens.

A diameter of the second inverting convex lens may be smaller than a diameter of the first inverting convex lens, and a long axis diameter of a cross-sectional shape of the first deformed beam may be smaller than a long axis diameter of the first sub-beam.

The non-inverting optic system may include a non-inverting convex lens positioned on a propagation path of the second sub-beam, and a non-inverting concave lens positioned to be spaced apart from the non-inverting convex lens and having a fourth curvature that may be the same as a third curvature that is a curvature of the non-inverting convex lens.

The cross-sectional shape of the second sub-beam may not be inverted when the second sub-beam sequentially passes through the non-inverting convex lens and the non-inverting concave lens.

A long axis diameter of a cross-sectional shape of the second deformed beam may be smaller than a long axis diameter of the second sub-beam.

A long axis diameter of a cross-sectional shape of the first deformed beam may be the same as a long axis diameter of a cross-sectional shape of the second deformed beam.

The integrated optic system may include a beam homogenizer positioned on propagation paths of the first deformed beam and the second deformed beam and configured to form the line beam by combining the first deformed beam and the second deformed beam and homogenizing energy distribution, and a field lens positioned after the beam homogenizer and configured to adjust a length of the line beam.

The beam division unit may include a first reflection member configured to reflect the laser beam, a beam splitter configured to generate the second sub-beam by transmitting a portion of the laser beam received from the first reflection member and reflecting a remaining portion of the laser beam, wherein the second sub-beam is directed to the non-inverting optic system, a second reflection member configured to generate the first sub-beam by reflecting a portion of the laser beam received from the beam splitter and to direct the first sub-beam to the inverting optic system.

According to an embodiment, a laser crystallization apparatus includes a laser light source configured to generate a laser beam, and a laser optic system configured to change a shape of the laser beam and irradiate the changed laser beam to a target object, where the laser optic system may include a beam division unit configured to divide the laser beam into first sub-beam and a second sub-beam, an inverting optic system configured to generate a first deformed beam by inverting a cross-sectional shape of the first sub-beam and reducing a diameter of the cross-sectional shape of the first sub-beam, a non-inverting optic system configured to generate a second deformed beam by reducing a diameter of a cross-sectional shape of the second sub-beam, and an integrated optic system configured to generate a line beam by integrating the first deformed beam and the second deformed beam.

According to an embodiment, it is possible to minimize the decrease of the laser beam energy by improving the beam uniformity without using a separate inverting module.

In addition, by improving the beam uniformity, the crystallization margin, which is an energy region where no blemishes spotting occur, may be improved.

### BRIEF DESCRIPTION OF THE DRAWINGS

FIG. 1 is a schematic drawing illustrating a laser crystallization apparatus according to an embodiment.

FIG. 2 is a specific drawing illustrating a laser optic system according to an embodiment.

FIG. 3 is a drawing illustrating a case where a cross-sectional shape of a first sub-beam having asymmetrical structure is inverted along a short axis.

FIG. 4 is a drawing illustrating a case where a cross-sectional shape of a first sub-beam having asymmetrical structure is inverted along a long axis.

FIG. 5 is a specific drawing illustrating the integrated optic system of FIG. 2.

### DETAILED DESCRIPTION

The present disclosure will be described more fully hereinafter with reference to the accompanying drawings, in which embodiments of the disclosure are shown. As those skilled in the art may realize, the described embodiments may be modified in various different ways, all of which, however, are not departing from the spirit or scope of the present disclosure.

To clearly describe the present disclosure, parts that are irrelevant to the description are omitted, and like reference numerals refer to like elements throughout the specification.

To clearly describe the present disclosure, the thicknesses of layers, films, panels, regions, etc., are enlarged for clarity. The thicknesses of some layers and areas are exaggerated.

It should be understood that when an element such as a layer, film, region, or substrate is referred to as being “on” another element, it can be directly on the other element or intervening elements may also be present. In contrast, when an element is referred to as being “directly on” another element, there are no intervening elements present therebetween. The word “on” or “above” means being disposed on or below the object portion, and does not necessarily mean being disposed on the upper side of the object portion based on a gravitational direction.

Unless explicitly stated to the contrary, the word “comprise” and variations such as “comprises” or “comprising” should be understood to imply the inclusion of stated elements but not the exclusion of any other elements.

The phrase “in a plan view” means viewing a target portion from the top, and the phrase “in a cross-sectional view” means viewing a cross-section of the target portion, in which the target portion is vertically cut, from the side.

Hereinafter, a laser optic system and a laser crystallization apparatus including the same according to an embodiment will be described in detail with reference to the drawings.

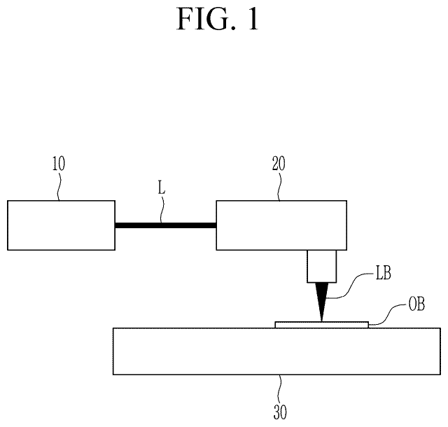

FIG. 1 is a schematic drawing illustrating a laser crystallization apparatus according to an embodiment.

As shown in FIG. 1, the laser crystallization apparatus according to an embodiment may include a laser light source 10, a laser optic system 20, and a stage 30.

The laser light source 10 may generate a laser beam L. The laser light source 10 may generate a laser beam by using a solid-state material such as Yb:YAG.

The laser optic system 20 may change a shape of the laser beam L to form a line beam LB and irradiate the changed laser beam to a target object OB. That is, the laser beam L generated by the laser light source 10 may be transformed into the line beam LB through the laser optic system 20, and be irradiated toward the target object OB placed on the stage 30.

The stage 30 may include a flat upper surface, and the target object OB may be placed on an upper surface of the stage 30. The target object OB may be disposed to face the laser optic system 20. When laser-crystallizing a thin-film transistor substrate, the target object OB may be an amorphous silicon layer located on the thin-film transistor substrate.

The laser optic system 20 may be moved in one direction or two directions perpendicular to each other by using a separate movable part (not shown), and the laser beam may scan an entire surface of the target object OB as the laser optic system 20 moves. However, the present disclosure is not limited thereto. By using the separate movable part (not shown), the stage 30 on which the target object OB is disposed may be moved to an opposite direction of the aforementioned one direction, and both the laser optic system 20 and the stage 30 may be moved.

As such, the laser crystallization apparatus according to an embodiment may irradiate the line beam LB to the target object OB, and crystallize amorphous silicon included in the target object OB into polycrystalline silicon.

Hereinafter, the laser optic system 20 that converts the laser beam L generated at the laser light source 10 into the line beam LB will be described in further detail.

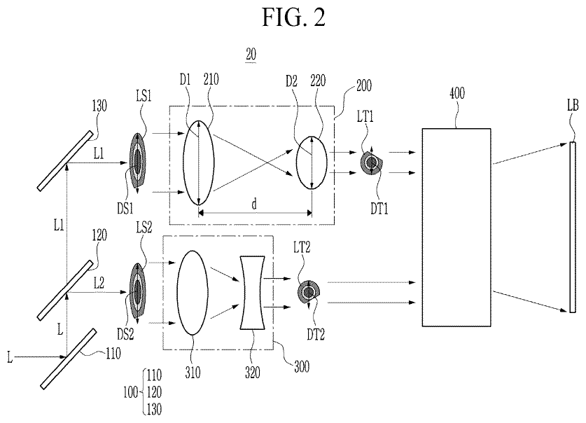

FIG. 2 is a specific drawing illustrating a laser optic system according to an embodiment.

As shown in FIG. 2, the laser optic system 20 may include a beam division unit 100, an inverting optic system 200, a non-inverting optic system 300, and an integrated optic system 400.

The beam division unit 100 may divide the laser beam L into a first sub-beam LS1 and a second sub-beam LS2.

The beam division unit 100 may include a first reflection member 110, a beam splitter 120, and a second reflection member 130.

The first reflection member 110 may reflect the laser beam L and transfer the reflected laser beam to the beam splitter 120.

The beam splitter 120 may transmit 50% of a laser beam LI received from the first reflection member 110 to a second reflection member 120, and may reflect the remaining 50% of a laser beam L2 to generate the second sub-beam LS2. The generated second sub-beam LS2 may be directed to the non-inverting optic system 300.

The second reflection member 130 may reflect the 50% of the laser beam L1 received from the beam splitter 120, and generate the first sub-beam LS1. The generated first sub-beam LS1 may be directed to the inverting optic system 200.

The inverting optic system 200 may generate a first deformed beam LT1 by inverting a cross-sectional shape of the first sub-beam LS1 and reducing a long axis diameter DS1 of the cross-sectional shape of the first sub-beam LS1.

The inverting optic system 200 may include a first inverting convex lens 210, and a second inverting convex lens 220.

The first inverting convex lens 210 may be positioned on a propagation path of the first sub-beam LS1, and the first sub-beam LS1 may be converged and diverged while passing through it.

The second inverting convex lens 220 may be positioned to be spaced apart from the first inverting convex lens 210. By adjusting a distance d between the first inverting convex lens 210 and the second inverting convex lens 220, the cross-sectional shape of the first sub-beam LS1, which passes sequentially through the first inverting convex lens 210 and the second inverting convex lens 220, may be inverted.

Hereinafter, with reference to the drawings, inversion of the cross-sectional shape of the first sub-beam will be described in further detail.

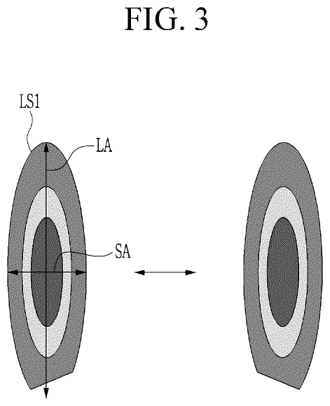

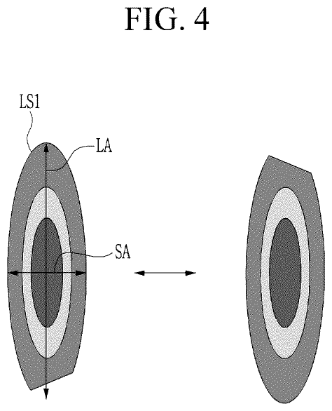

FIG. 3 is a drawing illustrating a case where a cross-sectional shape of a first sub-beam having asymmetrical structure is inverted along a short axis, and FIG. 4 is a drawing illustrating a case where a cross-sectional shape of a first sub-beam having asymmetrical structure is inverted along a long axis.

As shown in FIG. 3, as the first sub-beam LS1 sequentially passes through the first inverting convex lens 210 and the second inverting convex lens 220, the first sub-beam LS1 may undergo a long axis inversion, in which the cross-sectional shape of the first sub-beam LS1 is inverted along the long axis LA of the first sub-beam LS1.

As shown in FIG. 4, as the first sub-beam LS1 sequentially passes through the first inverting convex lens 210 and the second inverting convex lens 220, the first sub-beam LS1 may undergo a short axis inversion, in which the cross-sectional shape of the first sub-beam LS1 is inverted along the short axis SA of the first sub-beam LS1.

FIG. 2 illustrates that, as the first sub-beam LS1 sequentially passes through the first inverting convex lens 210 and the second inverting convex lens 220, the short axis inversion in which the cross-sectional shape of the first sub-beam LS1 is inverted along the short axis SA of the cross-sectional shape of the first sub-beam LS1 may occur.

According to an embodiment, a second curvature that is a curvature of the second inverting convex lens 220 may be greater than a first curvature that is a curvature of the first inverting convex lens 210. In addition, a diameter D2 of the second inverting convex lens 220 may be smaller than a diameter D1 of the first inverting convex lens 210.

Therefore, a long axis diameter DT1 of a cross-sectional shape of the first deformed beam LT1, formed as the first sub-beam LS1 sequentially passes through the first inverting convex lens 210 and the second inverting convex lens 220, may be smaller than the long axis diameter DS1 of the first sub-beam LS1.

As such, the inverting optic system 200 may generate the first deformed beam LT1 by inverting the cross-sectional shape of the first sub-beam LS1 and at the same time reducing the long axis diameter DT1 of the cross-sectional shape of the first sub-beam LS1.

According to an embodiment, the first deformed beam LT1 is obtained by reducing the long axis diameter DT1 of the cross-sectional shape of the first sub-beam LS1. However, the present disclosure is not limited thereto, and it is possible that the first deformed beam LT1 may be obtained by reducing the short axis diameter of the cross-sectional shape of the first sub-beam LS1.

The non-inverting optic system 300 may generate a second deformed beam LT2 by reducing a long axis diameter DS2 of a cross-sectional shape of the second sub-beam LS2.

The non-inverting optic system 300 may include a non-inverting convex lens 310, and a non-inverting concave lens 320.

The non-inverting convex lens 310 may be positioned on a propagation path of the second sub-beam LS2, and the second sub-beam LS2 may be converted while passing through it. According to an embodiment, a third curvature of the non-inverting convex lens 310 and the first curvature of the first inverting convex lens 210 may be the same.

The non-inverting concave lens 320 may be positioned to be spaced apart from the non-inverting convex lens 310. According to an embodiment, a fourth curvature that is a curvature of the non-inverting concave lens 320 may be the same as the third curvature of the non-inverting convex lens 310.

Therefore, as the second sub-beam LS2 sequentially passes through the non-inverting convex lens 310 and the non-inverting concave lens 320, the cross-sectional shape of the second sub-beam LS2 may not be inverted.

In addition, a long axis diameter DT2 of a cross-sectional shape of the second deformed beam LT2, formed as the second sub-beam LS2 sequentially passes through the non-inverting convex lens 310 and the non-inverting concave lens 320, may be smaller than the long axis diameter DS2 of the second sub-beam LS2.

As such, the non-inverting optic system 300 may generate the second deformed beam LT2 in which the cross-sectional shape of the second sub-beam LS2 is not inverted and at the same time the long axis diameter DS2 of the cross-sectional shape of the second sub-beam LS2 is not inverted.

In addition, since the long axis diameter DT1 of the cross-sectional shape of the first deformed beam LT1 may be the same as the long axis diameter DT2 of the cross-sectional shape of the second deformed beam LT2, it is easy to integrate the first deformed beam LT1 and the second deformed beam LT2 using the integrated optic system 400.

The integrated optic system 400 may generate the line beam LB by integrating the first deformed beam LT1 and the second deformed beam LT2.

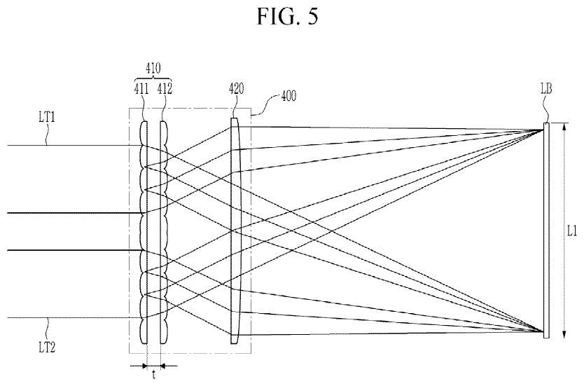

FIG. 5 is a specific drawing illustrating the integrated optic system of FIG. 2.

As shown in FIG. 2 and FIG. 5, the integrated optic system 400 may include a beam homogenizer 410 and a field lens 420.

The beam homogenizer 410 may be positioned on propagation paths of the first deformed beam LT1 and the second deformed beam LT2, and may combine the first deformed beam LT1 and the second deformed beam LT2.

The beam homogenizer 410 may form the line beam LB by homogenizing energy distribution of the first deformed beam LT1 and the second deformed beam LT2. Since the cross-sectional shape of the first deformed beam LT1 is inverted and the cross-sectional shape of the second deformed beam LT2 is not inverted, it is possible to form the line beam LB having a uniform energy distribution by combining the first deformed beam LT1 and the second deformed beam LT2.

The beam homogenizer 410 may include a first beam homogenizer 411 having a plurality of microlenses arranged and a second beam homogenizer 412 having a plurality of microlenses arranged. The first beam homogenizer 411 and the second beam homogenizer 412 may be spaced apart from each other and positioned opposite to each other. The beam homogenizer 410 may further homogenize the line beam LB by using the first beam homogenizer 411 and the second beam homogenizer 412.

The field lens 420 may be positioned behind the beam homogenizer 410, and may adjust a length LI of the line beam LB.

According to an embodiment, the laser beam is divided into the first sub-beam LS1 and the second sub-beam LS2 without using a separate inverting module, the inverting optical system 200 inverts the cross-sectional shape of the first sub-beam LS1 and reduces its diameter to generate the first deformed beam LT1, and the non-inverting optical system 300 reduces the diameter of the second sub-beam LS2 without inverting its cross-sectional shape to generate the second deformed beam LT2. And the integrated optical system 400 integrates the first deformed beam LT1 and the second deformed beam LT2 and generates the line beam LB having enhanced beam uniformity.

That is, even when the energy distribution of the laser beam is not uniform as the cross-sectional shape of the laser beam becomes asymmetric due to the thermal lensing effect, it is possible to obtain the line beam having uniform energy distribution by combining the inverted first deformed beam LT1 and the non-inverted second deformed beam LT2. Therefore, the decrease of energy of the laser beam may be minimized.

In addition, by improving the beam uniformity of the line beam, it is possible to improve the crystallization margin and distribution, which are energy regions where no blemishes occur.

While the present disclosure has been described above, it is to be understood that the present disclosure is not limited to the disclosed embodiments. On the contrary, it is intended to cover various modifications and equivalent arrangements included within the spirit and scope of the appended claims.

What is claimed is:

1. A laser optic system, comprising:
a beam division unit configured to divide a laser beam into a first sub-beam and a second sub-beam;
an inverting optic system configured to generate a first deformed beam by inverting a cross-sectional shape of the first sub-beam and reducing a diameter of the cross-sectional shape of the first sub-beam;
a non-inverting optic system configured to generate a second deformed beam by reducing a diameter of a cross-sectional shape of the second sub-beam; and
an integrated optic system configured to generate a line beam by integrating the first deformed beam and the second deformed beam.

2. The laser optic system of claim 1, wherein the inverting optic system comprises:
a first inverting convex lens positioned on a propagation path of the first sub-beam; and
a second inverting convex lens positioned to be spaced apart from the first inverting convex lens and having a second curvature that is greater than a first curvature that is a curvature of the first inverting convex lens,
wherein the cross-sectional shape of the first sub-beam is inverted when the first sub-beam sequentially passes through the first inverting convex lens and the second inverting convex lens.

3. The laser optic system of claim 2, wherein the first sub-beam forms the first deformed beam by a long axis inversion that is an inversion along a long axis of the cross-sectional shape of the first sub-beam or a short axis inversion that is an inversion along a short axis of the cross-sectional shape of the first sub-beam, when the first sub-beam sequentially passes through the first inverting convex lens and the second inverting convex lens.

4. The laser optic system of claim 2, wherein a diameter of the second inverting convex lens is smaller than a diameter of the first inverting convex lens; and
wherein a long axis diameter of a cross-sectional shape of the first deformed beam is smaller than a long axis diameter of the first sub-beam.

5. The laser optic system of claim 2, wherein the non-inverting optic system comprises:
a non-inverting convex lens positioned on a propagation path of the second sub-beam; and
a non-inverting concave lens positioned to be spaced apart from the non-inverting convex lens and having a fourth curvature that is the same as a third curvature that is a curvature of the non-inverting convex lens.

6. The laser optic system of claim 5, wherein the cross-sectional shape of the second sub-beam is not inverted when the second sub-beam sequentially passes through the non-inverting convex lens and the non-inverting concave lens.

7. The laser optic system of claim 5, wherein a long axis diameter of a cross-sectional shape of the second deformed beam formed is smaller than a long axis diameter of the second sub-beam.

8. The laser optic system of claim 5, wherein a long axis diameter of a cross-sectional shape of the first deformed beam is the same as a long axis diameter of a cross-sectional shape of the second deformed beam.

9. The laser optic system of claim 1, wherein the integrated optic system comprises:
a beam homogenizer positioned on propagation paths of the first deformed beam and the second deformed beam and configured to form the line beam by combining the first deformed beam and the second deformed beam and homogenizing energy distribution; and
a field lens positioned after the beam homogenizer and configured to adjust a length of the line beam.

10. The laser optic system of claim 1, wherein the beam division unit comprises:
a first reflection member configured to reflect the laser beam;
a beam splitter configured to generate the second sub-beam by transmitting a portion of the laser beam received from the first reflection member and reflecting a remaining portion of the laser beam, wherein the second sub-beam is directed to the non-inverting optic system;
a second reflection member configured to generate the first sub-beam by reflecting a portion of the laser beam received from the beam splitter and to direct the first sub-beam to the inverting optic system.

11. A laser crystallization apparatus, comprising:
a laser light source configured to generate a laser beam; and
a laser optic system configured to change a shape of the laser beam and irradiate the changed laser beam to a target object,
wherein the laser optic system comprises:
a beam division unit configured to divide the laser beam into a first sub-beam and a second sub-beam;
an inverting optic system configured to generate a first deformed beam by inverting a cross-sectional shape of the first sub-beam and reducing a diameter of the cross-sectional shape of the first sub-beam;
a non-inverting optic system configured to generate a second deformed beam by reducing a diameter of a cross-sectional shape of the second sub-beam; and
an integrated optic system configured to generate a line beam by integrating the first deformed beam and the second deformed beam.

12. The laser crystallization apparatus of claim 11, wherein the inverting optic system comprises:
a first inverting convex lens positioned on a propagation path of the first sub-beam; and
a second inverting convex lens positioned to be spaced apart from the first inverting convex lens and having a second curvature that is greater than a first curvature that is a curvature of the first inverting convex lens,
wherein the cross-sectional shape of the first sub-beam is inverted when the first sub-beam sequentially passes through the first inverting convex lens and the second inverting convex lens.

13. The laser crystallization apparatus of claim 12, wherein the first sub-beam forms the first deformed beam by a long axis inversion that is an inversion along a long axis of the cross-sectional shape of the first sub-beam or a short axis inversion that is an inversion along a short axis of the cross-sectional shape of the first sub-beam, when the first sub-beam sequentially passes through the first inverting convex lens and the second inverting convex lens.

14. The laser crystallization apparatus of claim 12, wherein a diameter of the second inverting convex lens is smaller than a diameter of the first inverting convex lens; and
wherein a long axis diameter of a cross-sectional shape of the first deformed beam is smaller than a long axis diameter of the first sub-beam.

15. The laser crystallization apparatus of claim 12, wherein the non-inverting optic system comprises:
a non-inverting convex lens positioned on a propagation path of the second sub-beam; and
a non-inverting concave lens positioned to be spaced apart from the non-inverting convex lens and having a fourth curvature that is the same as a third curvature that is a curvature of the non-inverting convex lens.

16. The laser crystallization apparatus of claim 15, wherein the cross-sectional shape of the second sub-beam is not inverted when the second sub-beam sequentially passes through the non-inverting convex lens and the non-inverting concave lens.

17. The laser crystallization apparatus of claim 15, wherein a long axis diameter of a cross-sectional shape of the second deformed beam is smaller than a long axis diameter of the second sub-beam.

18. The laser crystallization apparatus of claim 15, wherein a long axis diameter of a cross-sectional shape of the first deformed beam is the same as a long axis diameter of a cross-sectional shape of the second deformed beam.

19. The laser crystallization apparatus of claim 11, wherein the integrated optic system comprises:
a beam homogenizer positioned on propagation paths of the first deformed beam and the second deformed beam and configured to form the line beam by combining the first deformed beam and the second deformed beam and homogenizing energy distribution; and
a field lens positioned after the beam homogenizer and configured to adjust a length of the line beam.

20. The laser crystallization apparatus of claim 11, wherein the beam division unit comprises:
a first reflection member configured to reflect the laser beam;
a beam splitter configured to generate the second sub-beam by transmitting a portion of the laser beam received from the first reflection member and reflecting a remaining portion of the laser beam, wherein the second sub-beam is directed to the non-inverting optic system; and
a second reflection member configured to generate the first sub-beam by reflecting a portion of the laser beam received from the beam splitter and to direct the first sub-beam to the inverting optic system.
